(19) United States
(12) Patent Application Publication
(10) Pub. No.: US 2007/0051403 A1
(43) Pub. Date: Mar. 8, 2007

(54) Photoelectric Converter and Dye Sensitized Solar Cell

(75) Inventor: Akihiko ITAMI, Hachioji-shi, Tokyo (JP)

Correspondence Address: LUCAS & MERCANTI, LLP, 475 PARK AVENUE SOUTH, 15TH FLOOR, NEW YORK, NY, 10016, US

(73) Assignee: KONICA MINOLTA BUSINESS TECHNOLOGIES, INC., Tokyo (JP)

(21) Appl. No.: 11/425,617

(22) Filed: Jun. 21, 2006

(30) Foreign Application Priority Data
Sep. 2, 2005 (JP) JP2005-254531

(51) Int. Cl. H01L 31/00

(52) U.S. Cl. 136/263

(57) ABSTRACT

A photoelectric converter containing a conductive substrate having thereon a dye sensitized semiconductor electrode, a charge transport layer and a counter electrode, wherein the charge transport layer contains a charge transport material and an antioxidant.

### FIELD OF THE INVENTION

The present invention relates to a photoelectric converter and a dye sensitized solar cell, and more specifically relates to a dye sensitization type photoelectric converter and a dye sensitized solar cell which contains a charge transport material and an antioxidant.

### BACKGROUND OF THE INVENTION

As a solar cell, a single crystalline silicon solar cell, a polycrystalline silicon solar cell, an amorphous silicon solar cell and a compound solar cell such as cadmium telluride and indium copper selenide have been brought in practical use or are primary objects of research and development, however, in practical application, there are problems to be solved with respect to a manufacturing cost and securing of starting materials. On the other hand, many solar cells utilizing an organic material, which aims to achieve a larger area and a lower cost, have been proposed, however, there has been a problem such as low conversion efficiency and poor durability. In such a situation, there have been disclosed a photoelectric converter and a solar cell utilizing semiconductor particles sensitized by dye as well as a material and a manufacturing technology to manufacture the same (for example, refer to non-patent document 1, patent document 1). The proposed solar cell is a wet type solar cell employing a titanium oxide porous thin layer, which has been sensitized by a ruthenium complex, as a working electrode. The first advantage of this method is that it can provide a photoelectric converter at a low coat because of utilizing a low priced oxide semiconductor such as titanium oxide without purification. The second advantage is that it can convert light of the almost all wavelength region of visible light into electricity because of a broad absorption of the utilized dye.

However, in the proposed solar cell, an electrolyte solution containing iodine ion is utilized as an electrolyte in the cell. Such an electrolyte solution is liable to dry up resulting in exhibiting poor stability and short life as a solar cell. Since the material is liquid, workability in the manufacturing process is poor and it is also considered that an application to a flexible solar cell such as a plastic substrate is not fully easy. In this respect, there has been also an attempt to improve stability and workability of a solar cell by utilizing a solid electrolyte (a charge transport layer). For example, described is a photoelectric converter which is provided with a semiconductor electrode containing semiconductor particles, a charge transport layer and a counter electrode, wherein the charge transport layer contains a p-type inorganic semiconductor and a fused salt electrolyte (for example, refer to patent document 2). Further, also proposed has been photoelectric converter in which the charge transport layer is comprised of a transparent polymer containing an organic charge transport material (for example, refer to patent document 3). However, at the present stage, photoelectric conversion efficiency is not fully sufficient when using a p-type inorganic compound semiconductor, and the problem of durability due to oxidative degradation of an organic charge transport material has not been fully overcome.
Patent document 1 U.S. Pat. No. 4,927,721
Patent document 2 Japanese Patent Publication
   Open to Public Inspection (hereafter referred to as JP-A) No. 2001-230434
Patent document 3 JP-A No. 2004-356281
Non-patent document 1 Nature, 353, pp. 737-740 (1991)

### SUMMARY OF THE INVENTION

An object of the present invention is to provide an all-solid-state dye sensitized solar cell which can exhibit high photoelectric conversion efficiency and durability by incorporating an organic charge transport material in combination with an antioxidant in the charge transport layer of the solar cell.

One of the aspects of the present invention is a photoelectric converter containing a conductive substrate having thereon a dye sensitized semiconductor electrode, a charge transport layer and a counter electrode, wherein the charge transport layer contains a charge transport material and an antioxidant.

### BRIEF DESCRIPTION OF THE DRAWING

FIG. 1 is a schematic figure illustrating a basic construction of the photoelectric converter of the present invention.

### DESCRIPTION OF THE PREFERRED EMBODIMENTS

According to the present invention, an all-solid-state dye sensitized solar cell exhibiting high photoelectric conversion efficiency as well as superior durability, can be provided by employing an organic charge transport material in combination with an antioxidant in a charge transport layer of the solar cell. Specifically, the high molecular weight organic charge transport material having a molecular weight of 750-100,000 or the oligomer or polymer type charge transport material exhibits a high charge mobility and can be preferably utilized in the charge transport layer of the solar cell of the present invention.

The present invention will now be further detailed.

It was found that significantly improved was the life and the durability against environmental change of the photoelectric converter containing a conductive substrate having thereon a dye sensitized semiconductor electrode, a charge transport layer and a counter electrode, by incorporating an antioxidant in the charge transport layer containing an organic charge transport material.

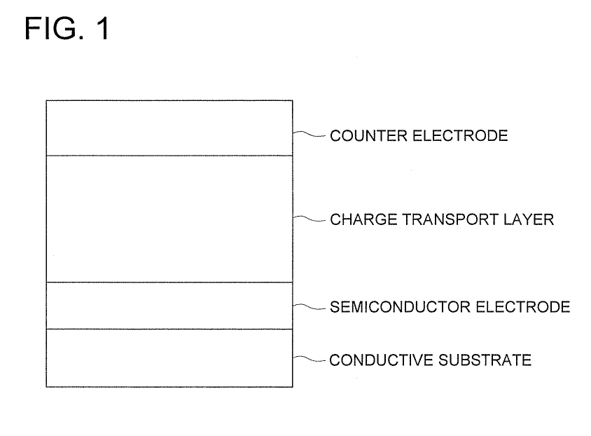

The photoelectric converter of the present invention basically contains a conductive substrate, a semiconductor electrode containing a dye, a charge transport layer and a counter electrode. FIG. 1 illustrates the basic construction of the photoelectric converter of the present invention. As a conductive substrate, preferable is a transparent conductive layer exhibiting a smaller absorbance or a smaller scattering of light. Specifically, employable are, for example, ITO, antimony doped tin oxide and zinc oxide. The photoelectric converter of the present invention may optionally have an additional layer. For example, an insulator layer or a semiconductor layer may be provided, as a blocking layer, between the conductive substrate and the dye sensitized semiconductor electrode in order to prevent leakage of generated charge. A metal oxide having a specific absorbing group may also be used as a blocking layer in order to improve the adhesiveness of the layer to the substrate in addition to the leakage blocking effect. Alternatively, a blocking layer may be provided between the dye sensitized semiconductor electrode and the charge transport layer.

A semiconductor electrode usable in the present invention will be explained. Examples of a semiconductor utilized in the semiconductor electrode of the photoelectric converter of the present invention include: elemental substances such as silicon and germanium; compounds containing an element of groups 3-5 or groups 13-15 in the periodic table; metal calcogenides; and metal nitrides.

Preferable calcogenide of metal includes such as oxide of titanium, tin, zinc, iron, tungsten, zirconium, hafnium, strontium, indium, cerium, yttrium, lanthanum, vanadium, niobium or tantalum; sulfide of cadmium, zinc, lead, silver, antimony or bismuth; selenide of cadmium or lead; and telluride of cadmium. Other compound semiconductors include such as phosphide of zinc, gallium, indium and cadmium; selenide of gallium-arsenic or copper-indium; sulfide of copper-indium and nitride of titanium.

Specific examples of a semiconductor according to the photoelectric converter of the present invention include such as TiO₂, SnO₂, Fe₂O₃, WO₃, ZnO, Nb₂O₅, CdS, ZnS, PbS, Bi₂S₃, CdSe, CdTe, GeP, InP, GaAs, CuInS₂ and Ti₃N₄, however, preferably utilized are TiO₂, ZnO, SnO₂, Fe₂O₃, WO₃, Nb₂O₅, CdS and PbS. Of these, more preferably employed are a metal oxide or a metal sulfide semiconductor, specifically preferably TiO₂ or Nb₂O₃ and most preferably TiO₂.

As a semiconductor utilized in the photoelectric converter of the present invention, the above-described plural number of semiconductors may be employed in combination. For example, a few types of the above-described metal oxide or metal sulfide may be utilized in combination, or titanium oxide semiconductor may be utilized by being mixed with 20 weight % of titanium nitride (Ti₃N₄). Further, zinc oxide/tin oxide complex described in J. Chem. Soc., Chem. Commun., 15 (1999) may also be applicable. When a component other than metal oxide or metal sulfide is used as a semiconductor, the weight content of the additional component based on the weight of the metal oxide or metal sulfide is preferably not more than 30%.

Any dye, which can spectrally sensitize the semiconductor of the present invention, is applicable. To widen the wavelength range of photoelectric conversion as well as to increase the conversion efficiency, mixing of not less than two types of dyes is preferable. Further, dyes to be mixed and mixing ratio thereof can be selected so as to fit the wavelength region and the intensity distribution of the aimed light source.

In view of photoelectron transfer-reaction activity, light fastness and photochemical stability, examples of a dye preferably used in combination with the semiconductor of the present invention include: a metal complex dye, a phthalocyanine dye, a porphyrin type dye, a polymethine dye and a solvent soluble pigment derivative in which a protective group to accelerate solvent solubility is introduced in the mother structure constituting the pigment,

Among known metal complex dyes, preferably applicable are ruthenium complex dyes, for example, disclosed in U.S. Pat. Nos. 4,927,721, 4,684,537, 5,084,365, 5,350,644, 5,463,057 and 5,525,440; JP-A Nos. 7-249750, 2001-223037 and 2001-226607; Published Japanese Translation of PCT International Publication No. 10-504512; and WO989/50393.

As a preferable porphyrin dye and a phthalocyanine dye, listed are the dyes disclosed, for example, in JP-A No. 2001-223037.

As a preferable methine dye, listed are, for example, conventionally known methine dyes, dyes disclosed in JP-A Nos. 11-35836, 11-158395, 11-163378, 11-214730, 11-214731, 10-093118, 11-273754, 2000-106224, 2000-357809 and 2001-052766, and Europe patent Nos. 892,411 and No. 911,841.

A photoelectric converter of the present invention can be sensitized by any one of the above described dyes and can exhibit the effects described in the present invention. Herein, sensitization by dye includes various types of embodiments such as adsorption of dye on the semiconductor surface and incorporation of dye into the porous structure of a semiconductor when the semiconductor has a porous structure.

Further, the total content of dye per 1 m² of a semiconductor layer (semiconductor electrode) is preferably in the range of 0.01-100 mmol, more preferably 0.1-50 mmol and specifically preferably 0.5-20 mmol.

Specifically, when the photoelectric converter of the present invention is utilized for a solar cell described later, it is preferred to utilize at least two types of dyes having different absorption wavelengths by mixing so as to widen the wavelength range of photoelectric conversion and enable to efficiently utilize sunlight.

A general method to adsorb dye on a semiconductor is that the dye is dissolved in a suitable solvent (such as ethanol) and a semiconductor is immersed in the solution for a long time.

When a photoelectric converter is prepared employing plural dyes in combination, a mixed solution of each compound may be used, or a semiconductor may be successively immersed in the solutions each containing a different compound. In the case when separate solutions are prepared for each compound and the semiconductor is successively immersed in each solution, the effects described in the present invention can be achieved regardless of the order of incorporation of such as the aforesaid compound or sensitization dye. Further, a photoelectric converter of the present invention can be prepared by mixing semiconductor particles on which the aforesaid compound is independently adsorbed.

The adsorption process may be performed either when a semiconductor is in a particle form, or after a semiconductor layer is formed on a support. The solution, in which a compound utilized for the adsorption process is dissolved, may be utilized at an ordinary temperature or by being heated at a temperature range not to decompose said compound and not to boil the solution. Further, similar to manufacturing of a photoelectric converter described later, adsorption of the aforesaid compound may be performed after coating of semiconductor particles (after formation of a photosensitive layer). Further, adsorption of the aforesaid compound may be performed by simultaneously coating semiconductor particles and the aforesaid compound of the present invention. Further, the compound which is not adsorbed can be removed by washing.

Further, in the case of a photoelectric converter having a highly porous semiconductor thin layer, it is preferable to complete adsorption process of dye (sensitization process of a photoelectric converter) before water (liquid or vapor) adsorbs on the semiconductor surface and in the voids of the semiconductor interior.

A photoelectric converter of the present invention may be surface treated by employing organic base. Examples of an organic base includes: diarylamine, triarylamine, pyridine, 4-t-butylpyridine, polyvinylpyridine, quinoline, pyperidine and amidine, however, preferable among them are pyridine, 4-t-butylpyridine and polyvinylpyridine.

The surface treatment can be carried out by immersing a photoelectric converter of the present invention in liquid amine or in a amine solution. When the above-described organic base is a liquid, it can be used as it is, and when the organic base is a solid, it can be dissolved in an organic solvent to use.

In the present invention, the photoelectric converter preferably contains an insulator layer or a semiconductor layer as a blocking layer between the conductive substrate and the semiconductor electrode. The blocking layer preferably contains a material which does not decompose nor deteriorate under the forming conditions of the semiconductor layer and the charge transport layer which are formed in the subsequent processes. A metal oxide layer or a silicon nitride layer formed via a sol-gel method is preferably employed as a blocking layer. Examples of the metal oxide include oxides of Si, Ti and Zr. The metal oxide layer is preferable because a homogeneous thin layer of a metal alcoxide precursor formed via a sol-gel reaction is easily obtained. More preferable is to use a slightly polymerized oligomer as a starting material, whereby the reaction rate is increased and a dense layer is obtained.

A charge transport layer will now be described. The charge transport layer of the present invention is a layer containing a compound which is solid at ambient temperature and transports electric charge. The charge transport layer includes (i) a layer formed by dispersing and mixing a low molecular weight charge transport material (also referred to as CTM) in a binder; or (ii) a layer of which binder itself is a charge transport material. These layers may be formed by dissolving a charge transport material and a binder in a solvent, followed by coating and drying the solution. Alternatively, when polymer charge transport materials having different average molecular weights are contained as major components, the charge transport layer may be formed by dissolving or dispersing the polymer charge transport materials in an appropriate solvent, and by coating the resulting liquid followed by drying. The charge transport layer of the present invention is different from the conventionally known “electrolyte” which is tonically dissociated. Since an electrolyte generally contains a solvent or liquid in order to dissociate ions, such electrolyte may be less stable due to the presence of the solvent or the liquid, compared to the photoelectric converter of the present invention.

According to the difference in molecular weight, the charge transport material may be classified into; (i) a low molecular weight charge transport material; (ii) a high molecular weight charge transport material; and (iii) a polymer charge transport material. A low molecular weight charge transport material means that the molecular weight is less than 750. A high molecular weight charge transport material means that the molecular weight is 750 or more and in the range where the chemical structure can be identified, even though several kinds of isomers or compounds having different structures may be included. And, a polymer charge transport material means that the chemical structure is difficult to uniquely determined, and a group of compounds is identified only by the molecular weight distribution. The molecular weights of the low molecular weight charge transport material and the high molecular weight charge transport material are determined by using a known FDMAS method. As for the low molecular weight charge transport material, the molecular weight may also be determined by identifying the chemical structure using NMR, IR or a MAS spectrum, first, to calculate the molecular weight. As for the polymer charge transport material, the molecular weight was determined, among several methods, by means of a GPC (Gel Permeation Chromatograph) method using polystyrene as the standard to obtain number average molecular weight, in the present invention. The measurement condition of GPC: Adding 1 ml of THF to 1 mg of specimen, and agitating with a magnetic stirrer at ambient temperature, the specimen was fully dissolved. Subsequently, after filtering with a membrane filter with a pore size of 0.45-0.50 μm, the solution was injected into GPC. The column was stabilized at 40° C., and about 100 μl of the specimen with a concentration of 1 mg/ml was injected, while 1 ml/minute of THF is being added, to measure the molecular weight distribution. A column of TSK-GEL SUPER HZM-M 4.6*150 or TSK Guard Column SUPER HZ-L produced by TOSOH CORP. was used. As a detector, a refractive index detector (IR detector) or a UV detector is preferably used. In the determination of molecular weight of the specimen, a calibration curve obtained by using about 10 standard samples of monodisperse polystyrene particles was used.

Examples of charge transport materials of the present invention are shown below, however, the present invention is not limited thereto.

Examples of a low molecular weight charge transport material include triphenylamine compounds represented by Formulas (I), (II) and (III) and benzidine compounds represented by Formula (III′). 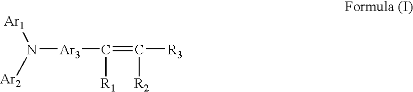
where Ar₁ and Ar₂ each represent an alkyl group or an aryl group, Ar₃ represents a phenylene group, Ar₃ and one of Ar₁ and Ar₂ may be joined to form a ring, R₁, R₂, and R₃ each represent a hydrogen atom, an alkyl group, or an aryl group, and R₂ and R₃ may be joined to form a ring.

Specific examples of a compound represented by Formula (I) are shown below, however, the present invention is not limited thereto: 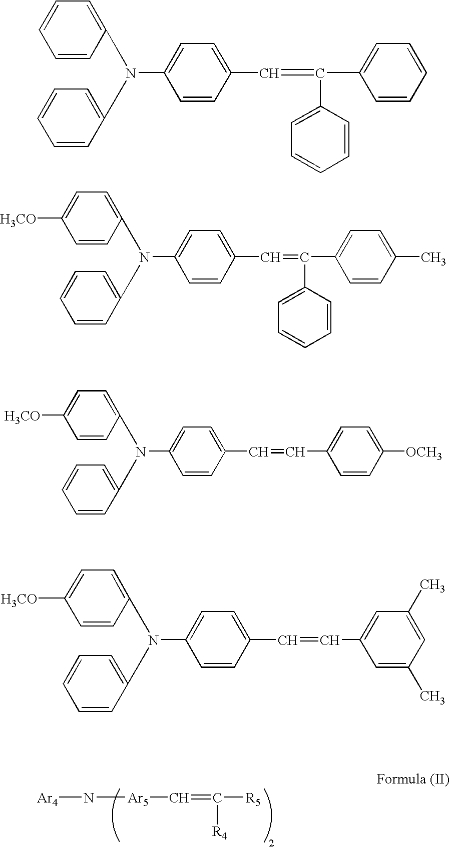
where Ar₄ represents an alkyl group or an aryl group, and Ar₅ represents a phenylene group, R₄ and R₅ each represent a hydrogen atom, an alkyl group, or an aryl group, and R₄ and R₅ may be joined to form a ring.

Specific examples of a compound represented by Formula (II) are shown below, however, the present invention is not limited thereto: 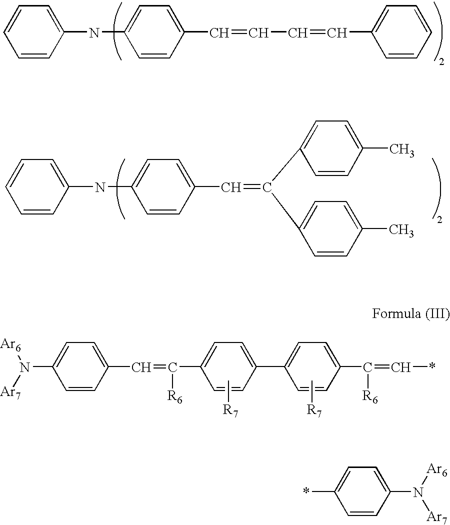
where Ar₆ and Ar₇ represent an alkyl group or an aryl group, the phenylene group bonded to the nitrogen atom and one of Ar₆ and Ar₇ may be joined to form a ring, R₆ represents a hydrogen atom, an alkyl group, or an aryl group, and R₇ represents a hydrogen atom, an alkyl group, an alkoxy group, or a halogen atom. 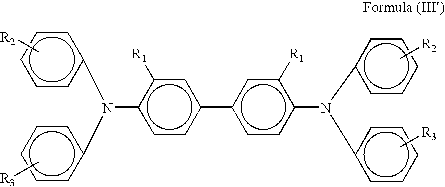
where R₁ represents an alkyl group, an alkoxy group, or a halogen atom, and R₂ and R₃ each independently represent a hydrogen atom, an alkyl group, an alkoxy group, a halogen atom, an alkoxy carbonyl group, or a substituted amino group.

Examples of a large molecular weight charge transport material include amines represented by Formula (IV): 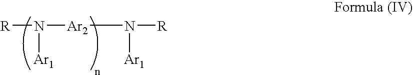
where Ar₁ represents an aromatic group which may be substituted or may not be substituted, Ar₂ represents a divalent aromatic group which may be substituted or may not be substituted, a divalent heterocycle group, or a compound represented by Formula (IV2), and R represents an alkyl group which may be substituted or may not be substituted, a monovalent aromatic group which may be substituted or may not be substituted, provided that a plurality of Ar₁, Ar₂ and R may be mutually different from each other, and n represents an integer: 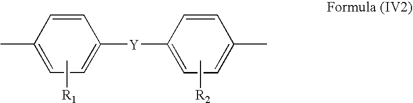
where Y represent an oxygen atom, a sulfur atom, —CH═CH—, or —CH2-CH2-, and R₁ and R₂ each represent a hydrogen atom or an alkyl group having 1 to 4 carbon atoms.

Typical examples of the chemical structure of Formula (IV) are shown below, provided that a mixture of compounds having different n values in Formula (IV) may be used as a charge transport material of the present invention.

Chemical Structures No. 1-10:

| No. | Ar₁ | Ar₂ | R |
|---|---|---|---|
| 1 | 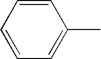 | 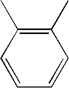 | 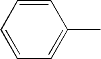 |
| 2 | 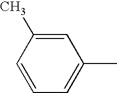 | 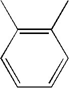 | 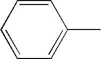 |
| 3 | 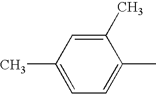 | 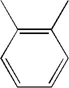 | 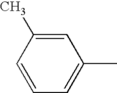 |
| 4 | 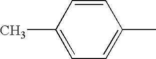 | 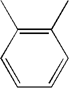 | CH₃ |
| 5 | 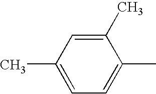 | 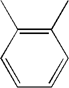 | 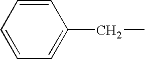 |
| 6 | 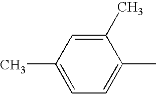 | 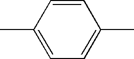 | 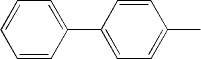 |
| 7 | 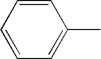 | 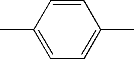 | 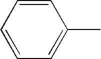 |
| 8 | 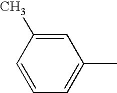 | 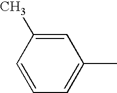 | 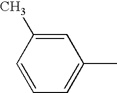 |
| 9 | 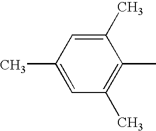 | 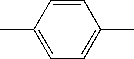 | 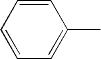 |
| 10 | 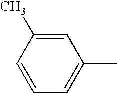 | 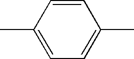 | 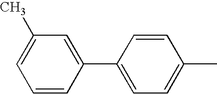 |

Examples of a polymer charge transport material include: resins represented by Formula (V), Formula (VI), and Formulas (VII1)-(VII2), resins represented by Compounds (VIII1)-(VIII8), poly-N-vinylcarbazole and polysilylene. Among the compounds represented by Formula (V), compound (V1) is specifically preferable since this compound has a function of self-organization. Further, a resin represented by Formula (V) exhibits smaller deterioration of photoelectric conversion efficiency due to irregular leakage of charge and provides a stable photoelectric conversion efficiency for a long term: 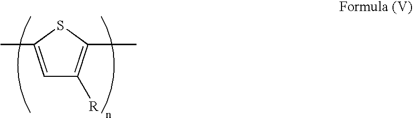
where R represents a hydrocarbon group which may be substituted or may not be substituted, and n represents the number of repeating units. 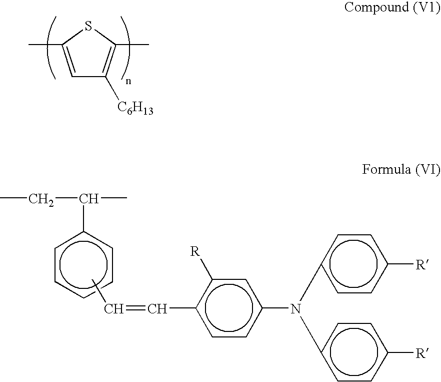
where R, R′, and R″ each represent a hydrogen atom, a lower alkyl group, a lower alkoxy group, and a halogen atom.

Examples of a stilbene group-containing monomer unit represented by Formula (VI) include are shown below.

Stilbene group-containing monomer unit Nos. 1-7: 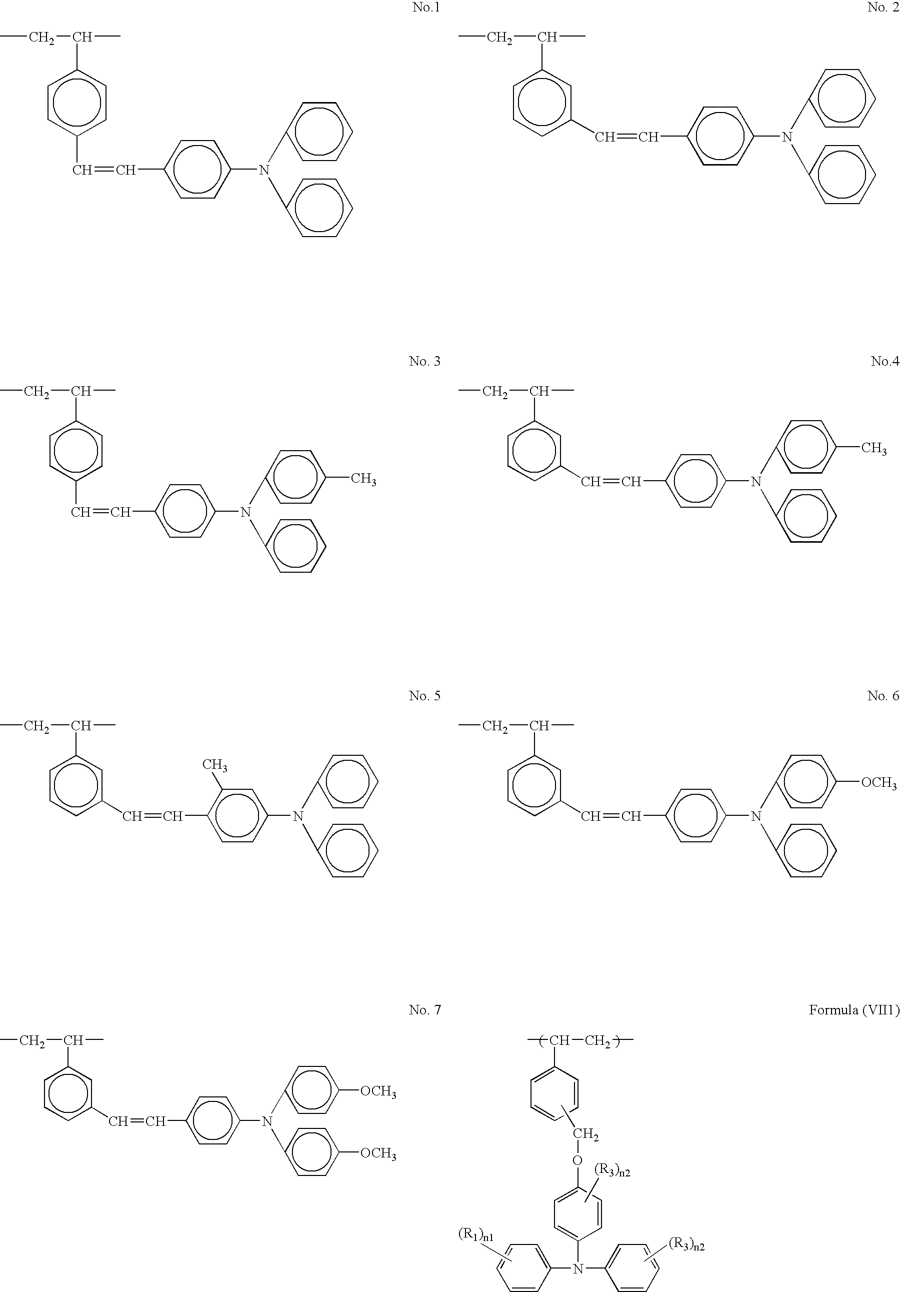 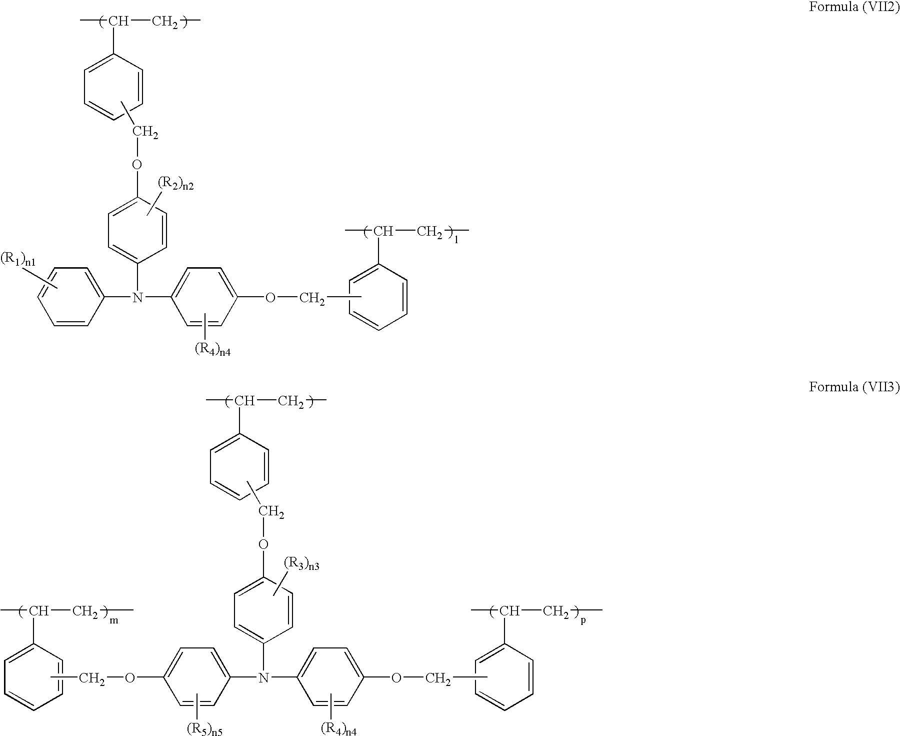
where, in Formulas (VII1)-(VII3), R₁, R₂, R₃, R₄, and R₅ each represent an alkyl group or an alkoxy group; n1 and n3 each represent an integer of 1-5; n2, n4, and n5 each represent an integer of 1-4; and l, m, and p each represent a value of larger than 0 and less than 1.

Specific examples of a polymer compound represented by Formulas (VII1)-(VII3) are shown below:

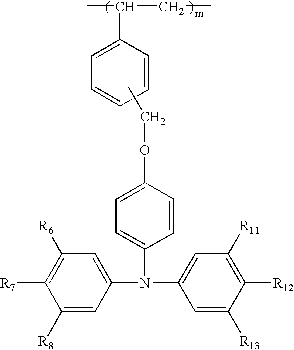

| | R₆ | R₇ | R₈ | R₁₁ | R₁₂ | R₁₃ |
|---|---|---|---|---|---|---|
| 1 | H | H | H | H | H | H |
| 2 | H | Me | H | H | H | H |
| 3 | H | Me | H | H | Me | H |
| 4 | Me | H | H | H | H | H |
| 5 | Me | H | H | H | Me | H |
| 6 | Me | H | H | Me | H | H |
| 7 | Me | H | Me | H | H | H |
| 8 | Me | H | Me | H | Me | H |
| 9 | Me | H | Me | Me | H | H |
| 10 | Me | H | Me | Me | H | Me |
| 11 | H | MeO | H | H | H | H |
| 12 | H | MeO | H | H | MeO | H |
| 13 | MeO | H | H | H | H | H |
| 14 | MeO | H | H | H | MeO | H |
| 15 | MeO | H | H | MeO | H | H |
| 16 | MeO | H | MeO | H | H | H |

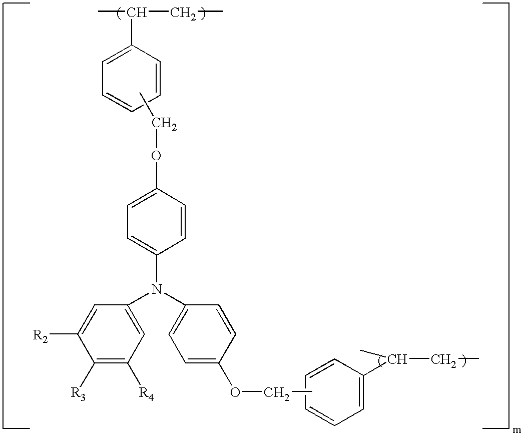

| | R₂ | R₃ | R₄ |
|---|---|---|---|
| 1 | H | H | H |
| 2 | H | Me | H |
| 3 | Me | H | H |
| 4 | Me | H | Me |
| 5 | H | H | H |
| 6 | MeO | H | H |
| 7 | MeO | MeO | MeO |

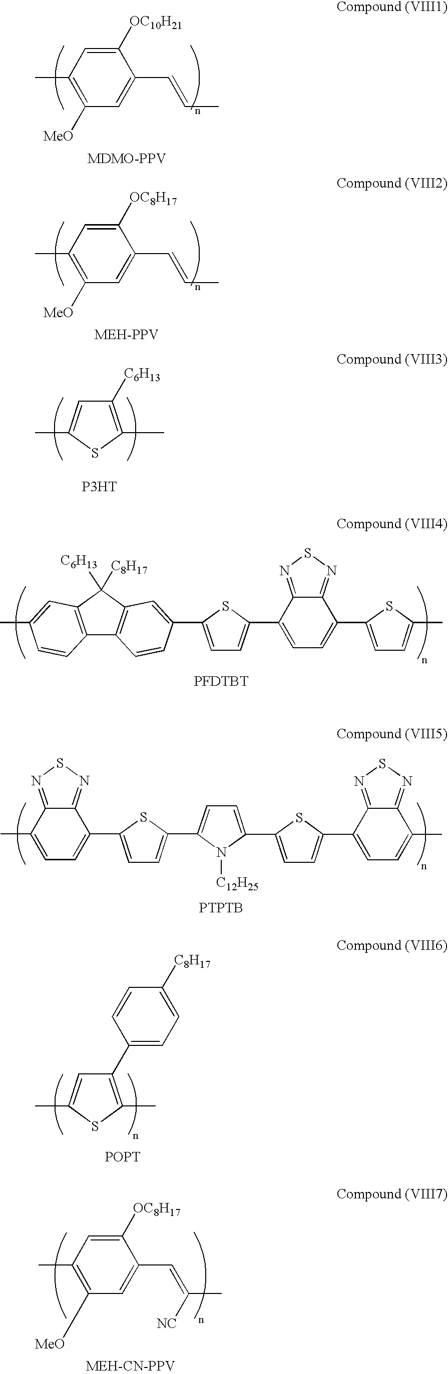

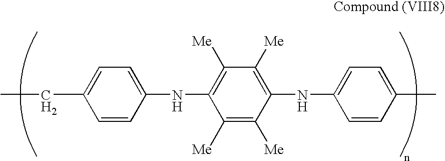

In the present invention, the molecular weight or average molecular weight of the charge transport material is preferably 750-100,000 and more preferably 1,000 in order to obtain a high photoelectric conversion efficiency and high durability. The reason will be as follows: the migration rate of electric charge is high and the tendency to form electric charge trap sites in the middle of the layer, is smaller, which causes degradation of efficiency.

Examples of a binder resin employable in the charge transport layer include: a polycarbonate resin (bisphenol A type and bisphenol Z type), a polyester resin, a methacryl resin, an acryl resin, a vinyl chloride resin, a polystyrene resin, a phenol resin, an epoxy resin, a polyurethane resin, a polyvinylidenechloride resin, an alkyd resin, a silicone resin, a polyvinyl carbazole resin, a polyvinyl butyral resin, a polyvinyl formal resin, a polyacrylate resin, a polyacrylamide resin and a phenoxy resin. These binders may be used alone or in combination of two or more resins. The content of such a resin is preferably 0-30 weight parts in 100 weight parts of the charge transport material. One of the aspects of the present invention is that an antioxidant is contained in the charge transport layer of the photoelectric converter.

The thickness of the charge transport layer of the photoelectric converter of the present invention is preferably 0.1-20 μm.

Examples of an antioxidant preferably used in the present invention include the following compounds, however, the present invention is not limited thereto.

(1) Radical Chain Inhibitor

Phenolic antioxidant (a hindered-phenol compound)

Amine antioxidant (a hindered amine compound, a diallyl

diamine compound, a diallyl amine compound)

Hydroquinone antioxidant

(2) Peroxide Decomposer

Sulfur-containing antioxidant (thioether)

Phosphoric acid-containing antioxidant (phosphite)

Among the above-mentioned antioxidants, radical chain inhibitors of (1) are preferable and a hindered-phenol or a hindered amine antioxidant is specifically preferable. Two or more kinds of oxidants may be used in combination, for example, a combination of a hindered-phenol antioxidant of (1) and an antioxidant of the thioether of (2) is preferable. Further, also preferable is a compound having the above-mentioned structural units, for example, a hindered-phenol structural unit, and a hindered amine structural unit in the molecule.

The content of a hindered-phenol antioxidant or a hindered amine antioxidant is preferably 0.01-20% by weight based on the weight of the charge transport layer. When the content is less than 0.01% by weight, deterioration of the conversion efficiency in long term use becomes notable, and when it is more than 20% by weight, deterioration of photoelectric conversion efficiency occurs even in the initial stage and the degradation in subsequent stages are still larger.

A hindered phenol denotes a compound or a derivative thereof which has a branched alkyl group in an ortho position relative to the hydroxyl group of the phenolic compound, provided that the hydroxyl group may be altered to an alkoxy group.

A hindered amine denotes a compound having a bulky organic group near the nitrogen atom. As a bulky organic group, for example, a branched alkyl group is cited, and preferable is, for example, a t-butyl group.

Examples of an antioxidant having a hindered phenol substructure are shown below, however, the present invention is not limited thereto.

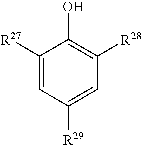

| Compound | R₂₇ | R₂₈ | R₂₉ |
|---|---|---|---|
| 1 | t-C₄H₉ | t-C₄H₉ | C₄H₉ |
| 2 | t-C₄H₉ | t-C₄H₉ | t-C₄H₉ |
| 3 | t-C₄H₉ | t-C₄H₉ | sec-C₄H₉ |
| 4 | t-C₄H₉ | t-C₄H₉ | CH₃ |
| 5 | t-C₄H₉ | t-C₄H₉ | C₂H₅ |
| 6 | t-C₄H₉ | CH₃ | CH₃ |
| 7 | t-C₄H₉ | CH₃ | t-C₄H₉ |
| 8 | t-C₄H₉ | CH₃ | C₄H₉ |
| 9 | t-C₄H₉ | CH₃ | sec-C₄H₉ |
| 10 | t-C₄H₉ | CH₃ | C₂H₅ |
| 11 | t-C₄H₉ | C₂H₅ | C₄H₉ |
| 12 | t-C₄H₉ | C₂H₅ | t-C₄H₉ |
| 13 | t-C₄H₉ | C₂H₅ | sec-C₄H₉ |
| 14 | t-C₄H₉ | C₂H₅ | CH₃ |
| 15 | t-C₄H₉ | C₂H₅ | C₂H₅ |
| 16 | C₂H₅ | C₂H₅ | sec-C₄H₉ |
| 17 | C₂H₅ | C₂H₅ | t-C₄H₉ |
| 18 | i-C₄H₉ | i-C₄H₉ | CH₃ |
| 19 | sec-C₄H₉ | sec-C₄H₉ | C₃H₇ |
| 20 | sec-C₄H₉ | sec-C₄H₉ | sec-C₄H₉ |

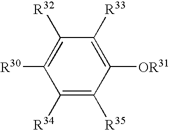

| Com- | | | | |
|---|---|---|---|---|
| pound | R³⁰ | R³¹ | R³²-R³⁵(Blank = H) | |
| 21 | C₇H₁₅ | C₇H₁₅ | R³²: C₁₂H₂₅(sec) | R³⁵: CH₃ |
| 22 | C₁₀H₂₁ | C₁₀H₂₁ | R³²: C₈H₁₇(i) | R³⁵: CH₃ |
| 23 | C₂₀H₄₁ | C₂₀H₄₁ | R³²: C₄H₉(t) | R³⁵: CH₃ |
| 24 | C₄H₉ | C₄H₉ | R³²: C₁₂H₂₅(sec) | R³⁵: CH₃ |
| 25 | C₄H₉ | C₄H₉ | R³²: C₈H₁₇(t) | R³⁵: CH₃ |
| 26 | C₄H₉ | C₄H₉ | R³²: C₁₈H₃₇(sec) | R³⁵: CH₃ |
| 27 | C₈H₁₇ | C₈H₁₇ | R³²: C₁₈H₃₇(sec) | R³⁵: CH₃ |
| 28 | C₈H₁₇ | C₈H₁₇ | R³²: C₈H₁₇(t) | R³⁵: CH₃ |
| 29 | C₈H₁₇ | C₈H₁₇ | R³²: C₄H₉(t) | R³⁵: CH₃ |
| 30 | C₈H₁₇ | C₈H₁₇ | R³²: C₄H₉(t) | R³⁵: CH₃ |
| 31 | C₁₂H₂₅ | C₁₂H₂₅ | R³²: C₄H₉(t) | R³⁵: CH₃ |
| 32 | C₁₂H₂₅ | C₁₂H₂₅ | R³²: C₈H₁₇(t) | R³⁵: CH₃ |
| 33 | C₁₂H₂₅ | C₁₂H₂₅ | R³²: C₁₂H₂₅(sec) | R³⁵: CH₃ |
| 34 | C₁₆H₃₃ | C₁₆H₃₃ | R³²: C₄H₉(sec) | R³⁵: CH₃ |
| 35 | C₁₆H₃₃ | C₁₆H₃₃ | R³²: C₄H₉(t) | R³⁵: CH₃ |
| 36 | C₁₆H₃₃ | C₁₆H₃₃ | R³²: C₁₂H₂₅(sec) | R³⁵: CH₃ |
| 37 | C₈H₁₇ | C₈H₁₇ | R³²: CH₃ R³⁴: CH₃ | R³⁵: CH₃ |
| 38 | C₁₂H₂₅ | C₁₂H₂₅ | R³²: CH₃ R³⁴: CH₃ | R³⁵: CH₃ |
| 39 | C₁₆H₃₃ | C₁₆H₃₃ | R³²: CH₃ R³⁴: CH₃ | R³⁵: CH₃ |
| 40 | CH₂CH═CH₃ | CH₂CH═CH₃ | R³²: C₈H₁₇(t) | R³⁵: C₈H₁₇(t) |
| 41 | C₈H₁₇ | C₈H₁₇ | R³²: C₄H₉₍ₜ₎ | R³⁵: C₄H₉₍ₜ₎ |
| 42 | C₈H₁₇ | C₈H₁₇ | R³²: 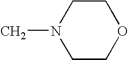 | R³⁵: 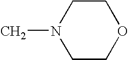 |
| 43 | C₈H₁₇ | C₈H₁₇ | R³²: 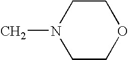 | R³⁵: 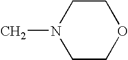 |
| 44 | C₁₈H₃₇ | C₁₈H₃₇ | R³²: C₁₂H₂₅ | R³⁵: CH₃ |
| 45 | C₁₆H₃₃ | C₁₆H₃₃ | R³²: C₁₂H₂₅ | R³⁵: C₁₂H₂₅ |
| 46 | C₁₂H₂₅ | C₁₂H₂₅ | R³²: C₁₆H₃₃(sec) | R³⁵: C₁₆H₃₃(sec) |
| 47 | C₂H₅ | C₂H₅ | R³²: (CH₂)₁₁OCH₃ | R³⁵: (CH₂)₁₁OCH₃ |
| 48 | 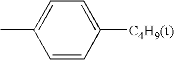 | 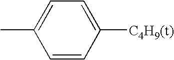 | R³²: C₁₁H₂₃ | R³⁵: C₁₁H₂₃ |
| 49 | C₁₈H₃₇ | C₁₈H₃₇ | R³²: C₁₂H₂₅(sec) | R³⁵: C₁₂H₂₅(sec) |
| 50 | CH₃ | (CH₂)₁₀Br | R³²: OCH₃ | |
| 51 | 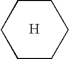 | 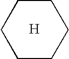 | R³²: C₁₆H₃₃ | R³⁵: C₁₆H₃₃ |
| 52 | C₈H₁₇ | C₈H₁₇ | R³²: 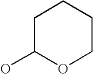 | R³⁵: 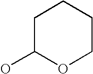 |
| 53 | 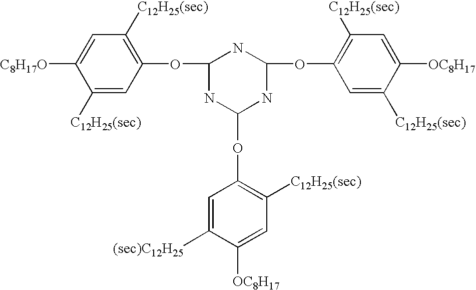 | | | |
| 54 | 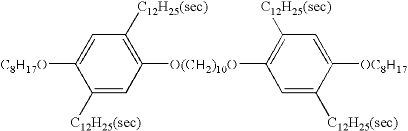 | | | |
| 55 | C₃H₇(i) | C₃H₇(i) | R³²: (CH₂)₁₁OCH₃ | |
| 56 | C₁₈H₃₇ | C₁₈H₃₇ | R³²: 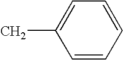 | R³⁵: CH₃ |
| 57 | 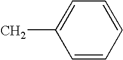 | 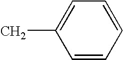 | R³²: C₁₆H₃₃(sec) | R³⁵: C₁₆H₃₃(sec) |
| 58 | C₁₂H₂₅ | C₁₆H₃₃ | R³³ : CH₃ | |
| 59 | C₁₈H₃₇ | C₁₈H₃₇ | R³³ : CH₃ | |
| 60 | C₄H₉ | C₄H₉ | R³³ : Cl | R³⁵: Cl |
| 61 | C₅H₁₁(sec) | C₅H₁₁(sec) | R³³ : N(CH₂CH₂OH)₂ | |
| 62 | C₃H₇(i) | 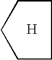 | R³²: C₈H₁₇(t) | R³⁵: CH₃ |
| 63 | C₇H₁₅(sec) | C₇H₁₅(sec) | R³²: CH₂CO₂C₂H₅ | R³⁵: CH₂CO₂C₂H₅ |
| 64 | C₈H₁₇ | C₈H₁₇ | R³²: COCH₃ | |
| 65 | C₁₆H₃₃ | C₁₆H₃₃ | R³²: COC₁₁H₂₃ | |
| 66 | C₁₂H₂₅(sec) | C₁₂H₂₅(sec) | R³²: CO₂C₂H₅ | |
| 67 | C₁₆H₃₃ | C₁₆H₃₃ | R³²: OC₂H₅ | R³⁵: OC₂H₅ |
| 68 | CH₂CO₂C₂H₅ | CH₂CO₂C₂H₅ | R³²: C₄H₉(t) | R³⁵: C₄H₉(t) |
| 69 | 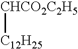 | C₃H₇ | R³²: C₄H₉(t) | R³⁵: CH₃ |
| 70 | C₂H₅ | 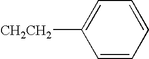 | R³²: NHCOCH₃ | |
| 71 | C₁₂H₂₅ | C₁₂H₂₅ | R³²: C₄H₉(t) | R³⁵: C₄H₉(t) |
| 72 | C₈H₁₇ | C₈H₁₇ | R³²: C₈H₁₇(t) | R³⁵: C₈H₁₇(t) |
| 73 | C₂H₅ | C₂H₅ | R³²: C₆H₁₃(t) | R³⁵: C₆H₁₃(t) |
| 74 | CH₃ | CH₃ | R³²: C₄H₉(t) | R³⁵: C₄H₉(t) |
| 75 | C₄H₉ | C₄H₉ | R³²: C₄H₉(t) | R³⁵: C₄H₉(t) |
| 76 | 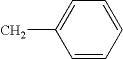 | 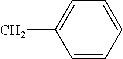 | R³²: C₄H₉(t) | R³⁵: C₄H₉(t) |
| 77 | C₁₈H₃₇ | C₁₈H₃₇ | R³²: C₄H₉(t) | R³⁵: C₄H₉(t) |
| 78 | C₁₆H₃₃ | C₁₆H₃₃ | R³²: C₄H₉(t) | R³⁵: C₄H₉(t) |
| 79 | 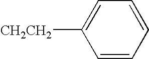 | 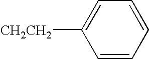 | R³²: C₄H₉(t) | R³⁵: C₄H₉(t) |
| 80 | C₄H₉ | C₄H₉ | R³²: C₅H₁₁(t) | R³⁵: C₅H₁₁(t) |
| 81 | C₂H₅ | C₂H₅ | R³²: C₅H₁₁(t) | R³⁵: C₅H₁₁(t) |
| 82 | C₃H₇ | C₃H₇ | R³²: C₅H₁₁(t) | R³⁵: C₅H₁₁(t) |
| 83 | CH₃ | CH₃ | R³²: C₅H₁₁(t) | R³⁵: C₅H₁₁(t) |
| 84 | 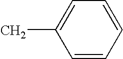 | 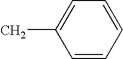 | R³²: C₅H₁₁(t) | R³⁵: C₅H₁₁(t) |
| 85 | CH₃ | CH₃ | R³²: C₆H₁₃(t) | R³⁵: C₆H₁₃(t) |
| 86 | C₃H₇ | C₃H₇ | R³²: C₆H₁₃(t) | R³⁵: C₆H₁₃(t) |
| 87 | C₄H₉ | C₄H₉ | R³²: C₆H₁₃(t) | R³⁵: C₆H₁₃(t) |
| 88 | 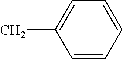 | 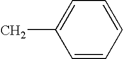 | R³⁵: C₆H₁₃(t) | R³⁵: C₆H₁₃(t) |
| 89 | CH₃ | CH₃ | R³²: C₈H₁₇(t) | R³²: C₈H₁₇(t) |
| 90 | C₂H₅ | C₂H₅ | R³²: C₈H₁₇(t) | R³²: C₈H₁₇(t) |
| 91 | C₃H₇ | C₃H₇ | R³²: C₈H₁₇(t) | R³²: C₈H₁₇(t) |
| 92 | C₄H₉ | C₄H₉ | R³²: C₈H₁₇(t) | R³²: C₈H₁₇(t) |
| 93 | 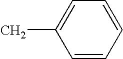 | 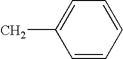 | R³²: C₈H₁₇(t) | R³²: C₈H₁₇(t) |
| 94 | CH₃ | CH₃ | R³²: C₁₂H₂₅(t) | R³²: C₁₂H₂₅(t) |
| 95 | C₂H₅ | C₂H₅ | R³²: C₁₂H₂₅(t) | R³²: C₁₂H₂₅(t) |
| 96 | C₃H₇ | C₃H₇ | R³²: C₁₂H₂₅(t) | R³²: C₁₂H₂₅(t) |
| 97 | C₄H₉ | C₄H₉ | R³²: C₁₂H₂₅(t) | R³²: C₁₂H₂₅(t) |
| 98 | 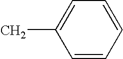 | 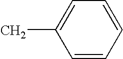 | R³²: C₁₂H₂₅(t) | R³²: C₁₂H₂₅(t) |

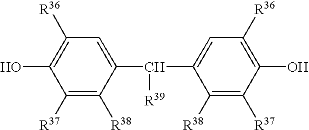

| Compound | R₃₆ | R₃₇ | R₃₈ | R₃₉ |
|---|---|---|---|---|
| 99 | CH₃ | H | H | H |
| 100 | CH₃ | CH₃ | H | H |
| 101 | CH₃ | t-C₄H₉ | H | H |
| 102 | t-C₄H₉ | t-C₄H₉ | H | H |
| 103 | t-C₄H₉ | H | H | CH₃ |
| 104 | CH₃ | H | H | t-C₄H₉ |
| 105 | H | CH₃ | C₃H₇ | CH₃ |
| 106 | t-C₄H₉ | H | CH₃ | H |
| 107 | CH₃ | H | CH₃ | C₃H₇ |
| 108 | t-C₄H₉ | H | CH₃ | C₅H₁₁ |
| 109 | CH₃ | CH₃ | H | C₉H₁₉ |
| 110 | C₁₂H₂₅ | CH₃ | H | H |
| 111 | t-C₄H₉ | H | CH₃ | C₄H₉ |

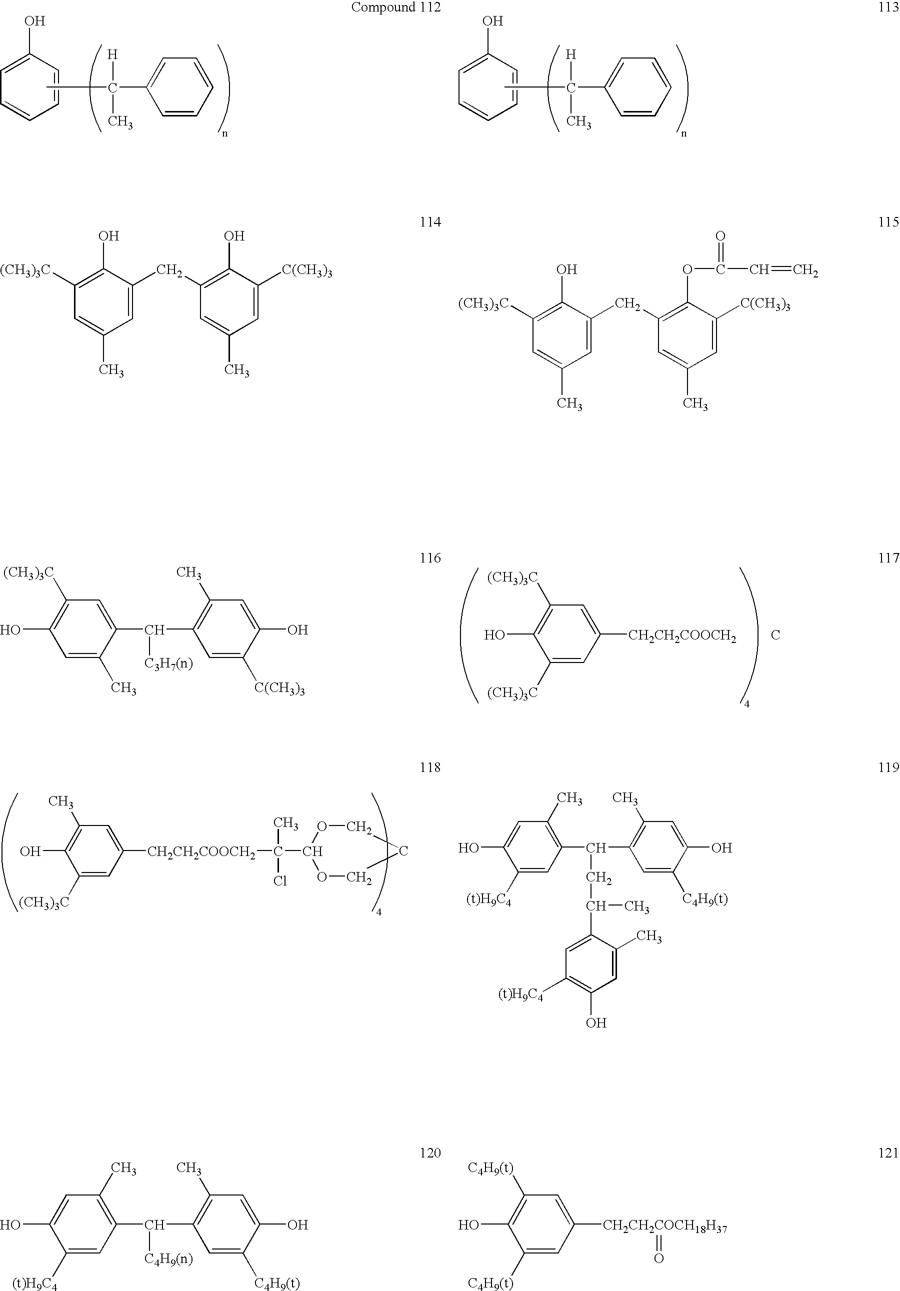

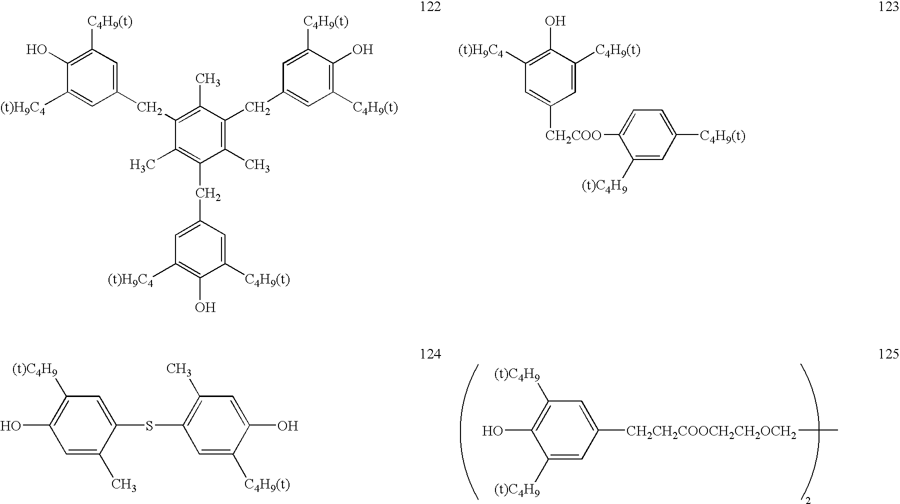

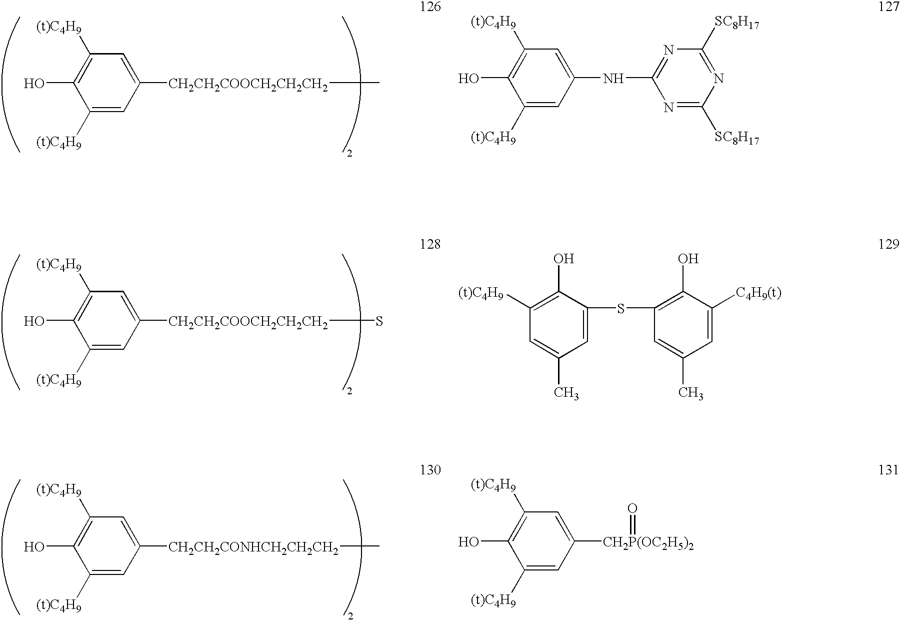

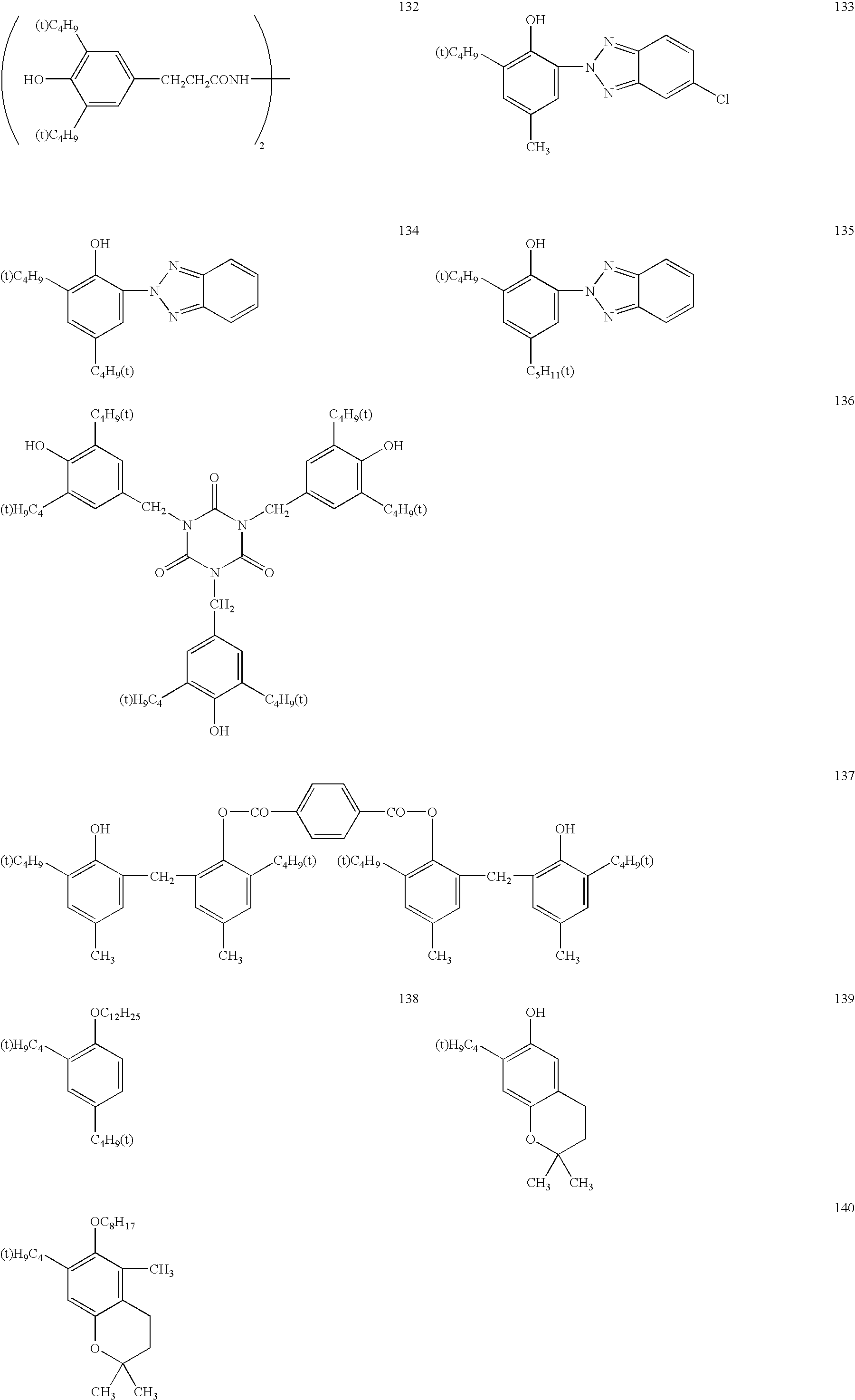

Examples of an antioxidant having a hindered amine substructure are shown below, however, the present invention is not limited thereto.

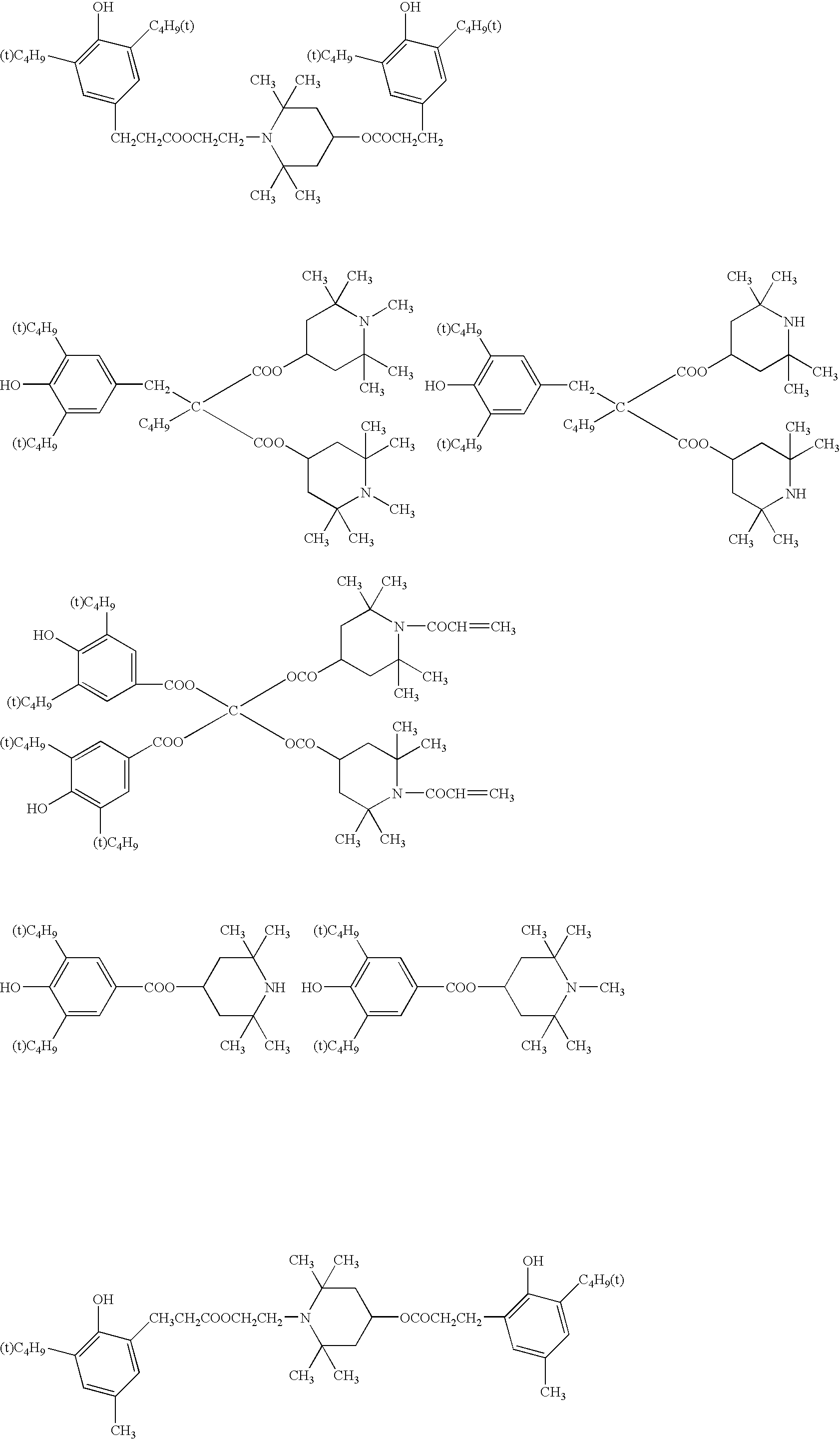

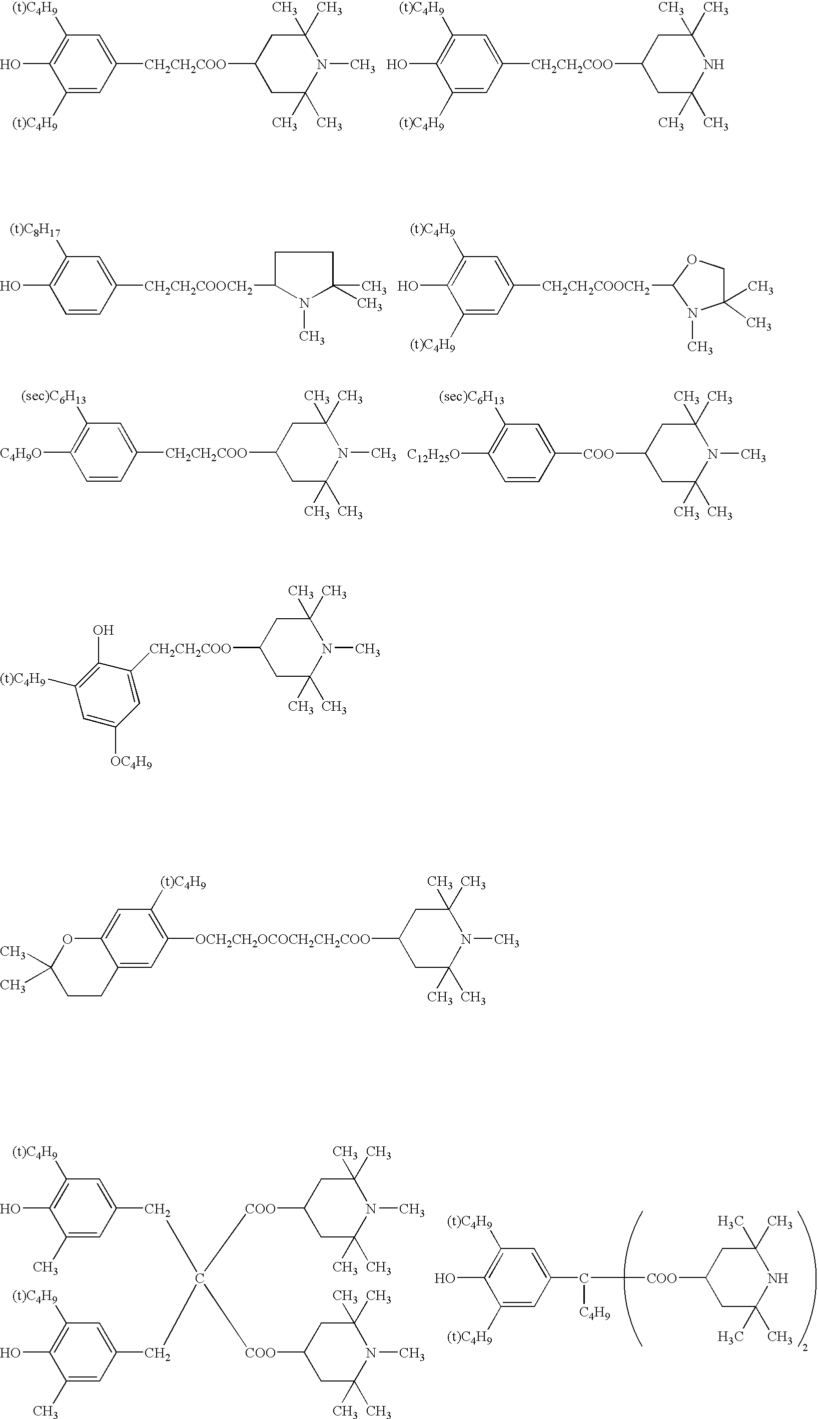

As an organic phosphorous compound, preferable are, for example, compounds represented by Formula: RO—P(OR)—OR, where R represents a hydrogen atom, an alkyl group which may be substituted or may not be substituted, an alkenyl group, or an aryl group.

As an organic sulfur-containing compound, preferable are, for example, compounds represented by Formula: R—S—R, where R represents a hydrogen atom, an alkyl group which may be substituted or may not be substituted, an alkenyl group, or an aryl group.

Examples of an antioxidant commercially available on the market include: hindered phenol antioxidants such as IRGANOX 1076, IRGANOX 1010, IRGANOX 1098, IRGANOX 245, IRGANOX 1330, IRGANOX 3114, IRGANOX 1076 and 3,5-di-t-butyl-4-hydroxybiphenyl; hindered amine antioxidants such as SANOL LS2626, SANOL LS765, SANOL LS770, SANOL LS744, TINUVIN 144, TINUVIN 622LD, MARK LA57, MARK LA67, MARK LA62, MARK LA68, and MARK LA63; thioether antioxidants such as SUMILISER TPS and SUMILISER TP-D; and phosphite antioxidants such as MARK 2112, MARK PEP-8, MARK PEP-24G, MARK PEP-36, MARK 329K and MARK HP-10.

Further, a charge transport layer may be appropriately added with a suitable low molecular weight compound such as binder resin, a low molecular weight charge transport material, a plasticizer and an ultraviolet absorbent, and a leveling agent at a suitable amount.

A preparation method of a semiconductor for a photoelectric converter material of the present invention will be now explained.

An embodiment of a semiconductor for a photoelectric converter material of the present invention includes a method such as to form the above-described semiconductor for a photoelectric converter material on a conductive support by calcination.

When the semiconductor for the photoelectric converter of the present invention is formed by calcination, sensitization process by employing the aforesaid compound and dye is preferably performed after the calcination. It is specifically preferable to rapidly perform the adsorption process after the calcination before water being adsorbed on the semiconductor.

When the semiconductor for the photoelectric converter of the present invention is a particle form, the semiconductor electrode (also referred to as the semiconductor layer) is preferably prepared by coating or spraying the semiconductor particles onto a conductive substrate. Further, when the semiconductor for the photoelectric converter of the present invention is a film and not held by a conductive substrate, the semiconductor electrode is preferably prepared by pasting the semiconductor film onto a conductive substrate.

In the following, a preparation process of a photoelectric converter material of the present invention will be specifically described.

First, a coating solution containing particles of a semiconductor is prepared. The semiconductor particles are preferably provided with a primary particle size as small as possible, and the primary particle size is preferably 1-5,000 nm and more preferably 2-50 nm. A coating solution containing semiconductor particles can be prepared by dispersing semiconductor particles in a solvent. The semiconductor particles dispersed in a solvent exists in the primary particle state. As a solvent, any one capable of dispersing semiconductor particles can be utilized and not specifically limited.

The aforesaid solvent includes such as water, an organic solvent and a mixed liquid of water and an organic solvent. As an organic solvent, utilized are, for example, alcohols such as methanol and ethanol, ketones such as acetone and acetyl acetone, and hydrocarbons such as hexane and cyclohexane. In a coating solution, a surfactant and a viscosity controlling agent (for example, polyhydric alcohol such as polyethylene glycol) may be appropriately incorporated. The concentration range of semiconductor particles in a solvent is preferably 0.1-70 weight % and more preferably 0.1-30 weight %.

A coating solution containing semiconductor particles having been prepared in the above manner is coated or sprayed on a conductive substrate and dried, followed by being calcinated in the air or an inert gas, whereby a semiconductor layer (a semiconductor film) is formed.

A coating method of a coating solution containing semiconductor particles includes such as roller coating, spin coating and dip coating.

A film prepared by coating and drying a coating solution on a conductive support is comprised of aggregate of semiconductor particles, and the particle diameters of the particles correspond to the primary particle diameters of utilized semiconductor particles.

Because a semiconductor particle aggregate film formed on a substrate such as a conductive substrate in this manner exhibits weak bonding power to a conductive support, and weak bonding power of particles each other and weak mechanical strength, it is preferable that the aforesaid semiconductor particle aggregate film is subjected to a calcinating process to enhance mechanical strength to form a calcinated film which firmly adheres to the conductive substrate.

In the present invention, this calcinated film may have any kinds of structures, however, is preferably a porous film (also referred to having voids or a porous layer).

Herein, a void ratio of a semiconductor thin film according to the present invention is preferably not more than 10 volume %, more preferably not more than 8 volume % and specifically preferably 0.01-5 volume %. Herein, a void ratio of a semiconductor thin film means a void ratio which is penetrating in the thickness direction and can be measured by use of an apparatus available on the market such as a mercury porosimeter (Shimazu Porelyzer 9220).

The layer thickness of a semiconductor layer, which has formed a calcinated film having a porous structure, is preferably not less than 10 nm and more preferably 100-10,000 nm.

In the calcination process, with respect to obtaining a calcinated film having the above-described void ratio by suitably adjusting the practical surface area of the calcinated film, the calcination temperature is preferably not higher than 1000° C., more preferably in the range of 200-800° C. and specifically preferably in a range of 300-800° C.

Further, the ratio of a practical surface area against an apparent surface area can be controlled by such as a particle size and a specific surface area of semiconductor particles and calcination temperature. For the purpose of enlarging the surface area of semiconductor particles and increasing the purity in the neighborhood of semiconductor particles resulting in increased electron injection efficiency from dye to semiconductor particles, a chemical plating treatment utilizing a tetrachlorotitanium aqueous solution or an electrochemical plating treatment utilizing a trichlorotitanium aqueous solution may be performed.

Sensitization process of a semiconductor is performed, in the above manner, by dissolving a dye in a suitable solvent and immersing a conductive substrate on which the aforesaid semiconductor has been provided by calcination. At that time, it is preferable that a conductive substrate, on which a semiconductor layer is formed by calcination, is preferably treated under reduced pressure or heated in advance to eliminate bubbles in the film so as to enabling invasion of a dye deeply into the interior of the semiconductor layer (the semiconductor film), and it is specifically preferable when the semiconductor layer (the semiconductor film) is a porous structured film.

The time to immerse a conductive substrate, on which a semiconductor has been provided by calcination, in a solution containing a dye is preferably 3-48 hours and more preferably 4-24 hours under a condition of 25° C., with respect to sufficient proceeding of such as adsorption by deep penetration of the aforesaid compound into a semiconductor layer, sufficient sensitization of a semiconductor as well as restraining disturbance of adsorption of a compound due to a decomposed product which has been formed by such as decomposition of the aforesaid compound in the solution. This effect is specifically significant in the case of a semiconductor film having a porous structure. However, the immersion time is a value under a condition of 25° C. and it is not the above-described case when temperature condition is varied.

When the above described immersion is carried out, the temperature of the solution containing a dye may be increased unless the solution is not boiled and unless the dye decomposes. The preferable temperature range is 10-100° C. and more preferably 25-80° C., however, it is not the case when the solvent boils in the aforesaid temperature range as described before.

After finishing immersion of a conductive substrate in a dye-containing solution, drying is carried out. Drying temperature is not specifically limited; however, drying is preferably performed in a range of an ambient temperature −100° C. and more preferably at approximately 50° C.

In the present invention, a blocking layer may be formed prior to forming the above described semiconductor layer. The material employed for the blocking layer and the calcination temperature thereof are preferably selected so that the blocking layer does not decompose nor deteriorate in the subsequent semiconductor layer forming process.

In the photoelectric converter of the present invention, a semiconductor layer adsorbed with the aforesaid dye (a dye sensitized semiconductor electrode) is provided on a conductive substrate and a charge transport layer containing a charge transport material and an antioxidant is provided thereon. Further, a counter electrode is provided on the charge transport layer.

As a substrate utilized in the photoelectric converter of the present invention and the solar cell of the present invention, employed can be a conductive material such as a metal plate and one having a structure in which conductive substance is provided on a non-conductive material such as a glass plate and a plastic film. Examples of a material utilized for a conductive substrate include metals (such as platinum, gold, silver, copper, aluminum, rhodium and indium), conductive metal oxides (such as indium-tin composite compound, those containing tin oxide doped with fluorine) and carbon. The thickness of a conductive substrate is not specifically limited, however, is preferably 0.3-5 mm.

Further, a conductive substrate is preferably essentially transparent and to be essentially transparent means to have a transmittance of light of not less than 10%, preferably not less than 50% and most preferably not less than 80%. To prepare a transparent conductive substrate, it is preferable to provide a conductive layer containing conductive metal oxide on the surface of a glass plate or a plastic film. A material for transparent plastic film includes tetraacetyl cellulose (TAC), polyethylene terephthalate (PET), polyethylene naphthalate (PEN), syndiotactic polystyrene (SPS), polyphenylene sulfide (PPS), polycarbonate (PC), polyarylate (PAr), polysulfone (PSF), polyester sulfone (PES), polyether imide (PEI), cyclic polyolefin and phenoxy bromide. To assure sufficient transparency, the coating amount of conductive metal oxide is preferably 0.01-100 g per 1 m² of a glass or plastic substrate. In the case of utilizing a transparent conductive substrate, it is preferable to use light which enters from the substrate side.

The surface resistance of a conductive substrate is preferably not more than 50 Ohm/sq and more preferably not more than 10 Ohm/sq.

### EXAMPLES

In the following, the present invention will be explained with reference to examples, however, the present invention is not limited thereto.

### Examples 1-23

Preparation of Photoelectric Converter

A dispersion of titanium oxide (P-25, manufactured by Nippon Aerosil Co.) was coated on the conductive surface side of a transparent conductive glass plate (having a surface resistance of 10 Ohm/sq) which had been coated with tin dioxide doped with fluorine, and the coated layer was dried at room temperature for 30 minutes, followed by calcinated at 450° C. for 60 minutes, whereby an electrode having a layer thickness of 10 μm was prepared. This electrode, after having been cooled, was adsorbed with a dye in a refluxing ethanol solution of Eosine Y Dye (3×10⁻⁴ mol/dm³) for 30 minutes.

Next, charge transport layers having the compositions shown in Table 1 were prepared: Each coating solution was prepared by dissolving CTM (charge transport material, 4 parts of a compound described in Table 1), an antioxidant (described in Table 1), bisphenol Z type polycarbonate (1 part) as a binder which may not be used (described in table 1) and titanium tetraisopropoxide (1 part) in 1oo parts of dichloromethane. Thus obtained solution was coated so as to make a dry layer thickness of 2 μm, followed by being dried at 100° C. for 60 minutes.

CTM-4 samples having different molecular weights were prepared as follows:

(1) In a 200 ml flask, 10.0 g of N—N′-bis(3,4-dimethylphenyl)-3,3′-dimethylbiphenyl-4,4′-diamine, 24.0 g of 4-ethoxycarbonylethyl-4′-iodophenyl, 11 g of potassium carbonate, 11.0 g of copper sulfate pentahydrate, and 30 ml of n-tridecane were charged and reacted at 230° C. for 1 hour under a nitrogen atmosphere. After the reaction, the product was cooled to ambient temperature and dissolved in 10 ml of toluene. Insoluble substance was removed by filtering. Then, the product was purified with a silicagel column chromatography using toluene to obtain 15.2 g of oily N—N′-bis(3,4-dimethylphenyl)-N—N′-bis-4-ethoxy carbonylethylphenyl[1-1′-biphenyl]-4,4′-diamine. Subsequently, 10 g of thus obtained diamine having two ester groups was put into a 100 ml flask, a solution of 2 g of potassium hydroxide dissolved in 50 ml of ethylene glycol was added, and the mixture was reacted at 150° C. for one hour under a nitrogen gas flow. After the reaction, the obtained liquid was cooled to ambient temperature, hydrochloric acid was added until the liquid turned to acidic, formed precipitate was separated by filtering, washed with distilled water, and dried to obtain 8.1 g of charge transport material 4′ having two carboxyl groups, which was a precursor of compound 4.

(2) Next, 7 g of compound 4′ was dissolved in 1 g of ethylene glycol, 10 g of toluene and 30 g of isopropanol. Further, 0.5 g of sulfuric acid was added as a catalyst. The solution was subjected to reaction at 80° C. for 60 minutes under a nitrogen gas flow. The product was poured into hexane and the precipitate was washed twice with methanol to obtain compound 4-1. The number average molecular weight of compound 4-1 was 20000 relative to styrene standard. Compound 4-2 was obtained in the same manner as compound 4-1 except that the reaction was carried out for 120 minutes. The number average molecular weight of compound 4-2 was 50000 relative to styrene standard. Compound 4-3 was obtained in the same manner as compound 4-1 except that the reaction was carried out at 90° C. for 120 minutes. The number average molecular weight of compound 4-3 was 120000 relative to styrene standard. Compound 4-4 was obtained in the same manner as compound 4-1 except that the reaction was carried out at 70° C. for 45 minutes. The number average molecular weight of compound 4-4 was 5000 relative to styrene standard. Sample Nos. 17-21 in Table 1 were prepared using compounds 4-1 to 4-4.

CTM-5 was prepared as follows:

In a dried and argon substituted container, 0.3472 g of 2,5-dibromo-3-hexylthiophene and 0.0447 g of naphthalene as an internal standard were charged. After argon substitution was carried out again, 5 ml of dried THF was added through a dried syringe under a nitrogen gas flow, followed by cooling to 0° C. Further, 0.53 ml of isopropyl magnesium chloride-THF solution (2.0 mol/l) was added (1.1 mmol, 1 eq) through a dried syringe under a nitrogen gas flow, and stirred for 30 minutes at 0° C. In another dried and argon substituted container, 0.0030 g of 1,3-bis-diphenylphosphinopropane nickel chloride(II) (0.006 mmol, 0.50 mol % based on mol of monomer) and an adequate amount of distilled toluene were charged, and boiled together under a reduced pressure to dry 1,3-bis-diphenylphosphinopropane nickel chloride(II). Further, 3 ml of dried THF was added through a dried syringe under a nitrogen gas flow and the mixture was added to the above thiophene solution which was monometallized by means of Grignard reagent, followed by stirring the mixture at ambient temperature (about 20° C.) for 10 hours. The sampling was carried out through a dried syringe under a nitrogen gas flow. After the reaction, water was added and then the product was extracted using chloroform. The organic phase was washed with water, and dried with magnesium sulfate anhydrous. By removing the solvent under a reduced pressure, black solid was obtained. The molecular weight and the molecular weight distribution of obtained poly-3-hexylthiophene were measured by means of GPC, and found to be 38000 and 1.30, respectively.

Photoelectric converters 1-22 (Sample Nos. 1-22 in Table 1) were prepared by placing a transparent conductive glass plate (FTO) as a counter electrode on each of the CTM layers described above. The transparent conductive glass plate (FTO) was prepared by coating fluorine-doped tin oxide on a glass plate followed by further coating platinum.

Photoelectric Converter 23

Photoelectric converter 23 was prepared in the same manner as photoelectric converter 2 (Sample No. 2 in Table 1) except that, prior to coating a dispersion of titanium oxide, a blocking layer was formed on the conductive surface side of the transparent conductive glass plate by applying the following coating liquid:

Coating Liquid

| | |
|---|---|
| Ethyl silicate Oligomer (Silicate 40, | 100 weight parts |
| produced by Tama Chemicals Co., Ltd.) | |
| Tetraethoxysilane | 50 weight parts |
| Ion-exchanged water | 20 weight parts |

Application of the above coating liquid was carried out by using a spin coater at 1000 rpm, followed by drying the layer at 150° C. for 20 minutes as the first drying process. The thickness of the layer at this stage was 0.2 μm.

Preparation of Solar Cells 1-23:

Lead wires were connected after the side surfaces of each of photoelectric converters 1-23 had been sealed with a resin. Three lots for each of Solar Cells 1-23 were prepared.

Evaluation of Photoelectric Conversion Efficiency of Solar Cells:

Photoelectric conversion efficiency, when light having an intensity of 100 mW/m² was irradiated on each of solar cells 1-23 prepared above, was measured by use of Solar Simulator (a low energy spectral sensitivity meter CEP-25, produced by JASCO Corp.), which is shown in Table 1. Each photoelectric conversion efficiency shown in Table 1 is an average of measurements on three solar cells having the same constitution and prepared by the same method.

Evaluation of Photoelectric Conversion Efficiency (Energy Conversion Efficiency):

A test was carried out to evaluate photoelectric conversion efficiency (energy conversion efficiency η) of each of the above-described solar cells 1-22. This evaluation test was performed by use of Solar Simulator (WXS-85-H Type, produced by Wacom Electric Co., Ltd.) according to the following procedure by irradiating pseudo-sunlight of 100 mW/cm² obtained from a xenon lamp through an AM Filter (AM-1.5).

With respect to each solar cell immediately after preparation, a current-voltage characteristic was measured at ambient temperature by use of an I-V tester to determine a short circuit current (Jsc), an open circuit voltage (Voc) and a fill factor (F. F.), from which a photoelectric conversion efficiency (η (%)) was determined. Herein, photoelectric conversion efficiency (η (%)) was calculated based on the following Equation (A).
η=100×(Voc×Jsc×F.F.)/P (A)
wherein, P represents an intensity of incident light [mW·cm⁻²], Voc represents an open circuit voltage [V], Jsc represents a short circuit current density [mA·cm⁻²] and F. F. represent a fill factor. Photoelectric conversion efficiency obtained in this manner was shown in table 1.

Evaluation of Durability:

The decreasing ratio after 100 hours of light irradiation by a solar simulator at 100 mW/m² was shown in Table 1.

TABLE 1

| | | | | | Photoelectric | | |
|---|---|---|---|---|---|---|---|
| Sample | | Molecular | | | conversion | Decrease | |
| No. | CTM | weigh | Antioxidant | Binder | efficiency (%) | ratio (%) | Remarks |
| 1 | 1 | 516 | — | *1 | 0.15 | 46 | Comparison |
| 2 | 1 | 516 | Irganox 1010 | BPZ | 0.21 | 14 | Invention |
| 3 | 1 | 516 | Irganox 245 | BPZ | 0.20 | 16 | Invention |
| 4 | 1 | 516 | Irganox 1425WL | BPZ | 0.20 | 19 | Invention |
| 5 | 1 | 516 | Sumilizer BHT | BPZ | 0.24 | 12 | Invention |
| 6 | 1 | 516 | Sumilizer GA-80 | BPZ | 0.21 | 17 | Invention |
| 7 | 1 | 516 | Sumilizer GM | BPZ | 0.21 | 18 | Invention |
| 8 | 1 | 516 | Sumilizer BP-76 | BPZ | 0.20 | 19 | Invention |
| 9 | 1 | 516 | Tinuvin 765 | BPZ | 0.24 | 9 | Invention |
| 10 | 1 | 516 | Sanol LS-2626 | BPZ | 0.25 | 11 | Invention |
| 11 | 1 | 516 | Sanol LS-440 | BPZ | 0.21 | 10 | Invention |
| 12 | 1 | 516 | Tinuvin 622LD | BPZ | 0.25 | 9 | Invention |
| 13 | 2 | 643 | Sumilizer BHT | BPZ | 0.24 | 13 | Invention |
| 14 | 3 | 822 | Irganox 1010 | BPZ | 0.51 | 18 | Invention |
| 15 | 3 | 1592 | Irganox 1010 | — | 0.69 | 16 | Invention |
| 16 | 3 | 3000* | Irganox 1010 | — | 0.78 | 15 | Invention |
| 17 | 4 | 5000* | Sumilizer BHT | — | 0.72 | 13 | Invention |
| 18 | 4 | 20000* | Sumilizer BHT | — | 0.78 | 14 | Invention |
| 19 | 4 | 50000* | Sumilizer BHT | — | 0.81 | 16 | Invention |
| 20 | 4 | 120000* | Sumilizer BHT | — | 0.69 | 15 | Invention |
| 21 | 4 | 20000* | — | — | 0.63 | 37 | Comparison |
| 22 | 5 | 45000* | Sumilizer BHT | — | 1.02 | 22 | Invention |
| 23 | 1 | 516 | Irganox 1010 | BPZ | 0.19 | 14 | Invention |

*1 Bisphenol Z type polycarbonate (BPZ),
*number average molecular weight

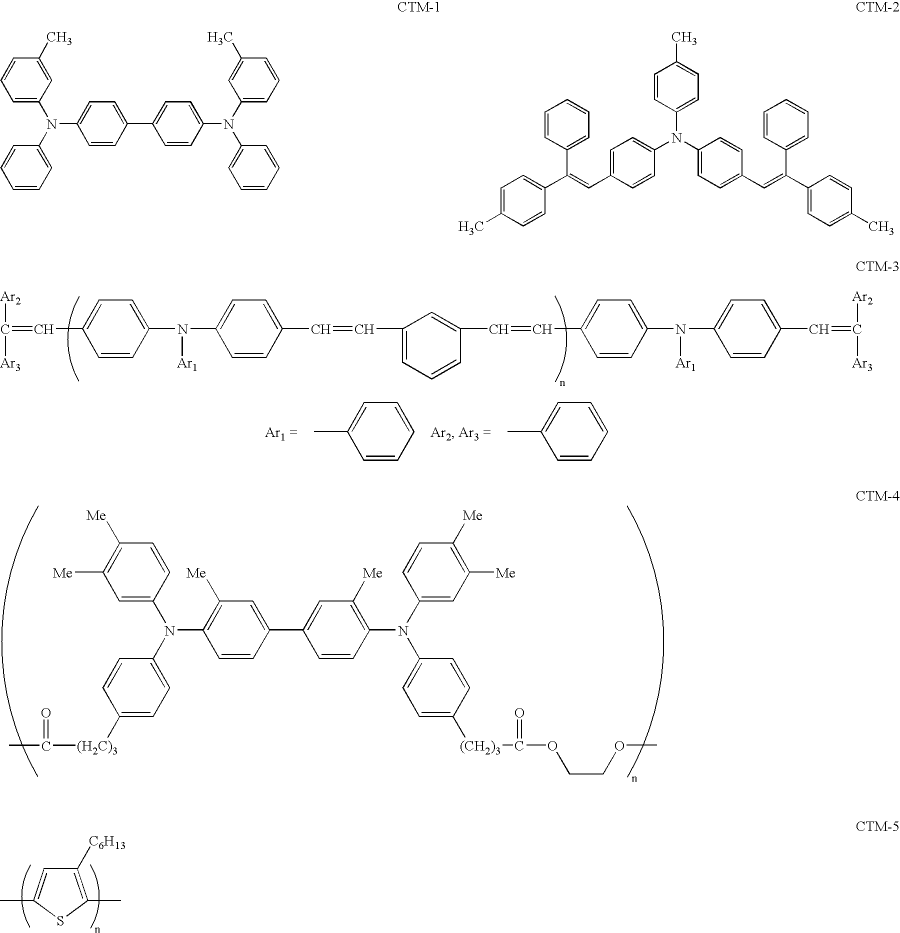

It is clear from Table 1 that solar cells of the present invention exhibit high photoelectric conversion efficiency and superior stability without deterioration of photoelectric conversion efficiency.

What is claimed is:

1. A photoelectric converter comprising a conductive substrate having thereon a dye sensitized semiconductor electrode, a charge transport layer and a counter electrode, wherein the charge transport layer contains a charge transport material and an antioxidant.

2. The photoelectric converter of claim 1, wherein the antioxidant comprises a hindered amine or a hindered phenol.

3. The photoelectric converter of claim 1, wherein the weight content of the antioxidant is 0.01-20% by weight based on the weight of the charge transport layer.

4. The photoelectric converter of claim 1, wherein the charge transport layer comprises a charge transport material having a molecular weight of 750-100,000.

5. The photoelectric converter of claim 1, wherein the charge transport layer comprises a polymer charge transport material and the antioxidant but the charge transport layer comprises no binder resin.

6. The photoelectric converter of claim 5, wherein the polymer charge transport material is a conductive polymer.

7. The photoelectric converter of claim 1, wherein the photoelectric converter further comprises an insulator layer or a semiconductor layer as a blocking layer between the conductive substrate and the semiconductor electrode.

8. The photoelectric converter of claim 1, wherein a thickness of the semiconductor electrode is 100-10000 nm.

9. The photoelectric converter of claim 1, wherein a thickness of the charge transport layer is 0.1-20 μm.

10. A dye sensitized solar cell comprising the photoelectric converter of claim 1.
